(19) United States
(12) Patent Application Publication
(10) Pub. No.: US 2009/0301388 A1
(43) Pub. Date: Dec. 10, 2009

(54) CAPSULE FOR HIGH PRESSURE PROCESSING AND METHOD OF USE FOR SUPERCRITICAL FLUIDS

(75) Inventor: MARK P. D'EVELYN, Goleta, CA (US)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Soraa Inc., Goleta, CA (US)

(21) Appl. No.: 12/133,365

(22) Filed: Jun. 5, 2008

(51) Int. Cl. C30B 19/00

(52) U.S. Cl. 117/71; 117/206; 117/11

(57) ABSTRACT

An improved capsule for processing materials or growing crystals in supercritical fluids. The capsule is scalable up to very large volumes and is cost effective according to a preferred embodiment. In conjunction with suitable high pressure apparatus, the capsule is capable of processing materials at pressures and temperatures of 0.2-8 GPa and 400-1500° C., respectively. Of course, there can be other variations, modifications, and alternatives.

### CROSS-REFERENCES TO RELATED APPLICATIONS

NOT APPLICABLE

### STATEMENT AS TO RIGHTS TO INVENTIONS MADE UNDER FEDERALLY SPONSORED RESEARCH OR DEVELOPMENT

NOT APPLICABLE

### REFERENCE TO A “SEQUENCE LISTING,” A TABLE, OR A COMPUTER PROGRAM LISTING APPENDIX SUBMITTED ON A COMPACT DISK.

NOT APPLICABLE

### BACKGROUND OF THE INVENTION

The invention relates generally to a device and method for processing supercritical fluids. In particular, the invention provides a capsule device and related method to be used with high pressure apparatus. More particularly, the invention relates to a capsule used in conjunction with a high-pressure apparatus for processing at least one material in a supercritical fluid. Merely by way of example, the invention can be applied to growing crystals of GaN, AlN, InN, InGaN, AlGaN, AlInGaN, and others for manufacture of bulk or patterned substrates. Such bulk or patterned substrates can be used for a variety of applications including optoelectronic devices, lasers, light emitting diodes, solar cells, photodetectors, and integrated circuits, transistor devices, and other device structures.

Supercritical fluids (also referred to hereinafter as “SCF”) may be used to process a wide variety of materials. Examples of SCF applications include extractions in supercritical carbon dioxide, decomposition of waste materials or biofuels in supercritical water, the growth of quartz crystals in supercritical water, and the synthesis of a variety of nitrides in supercritical ammonia.

Processes that employ supercritical fluids are commonly performed at high pressure and high temperature (also referred hereinafter as “HPHT”) within a pressure vessel. Most conventional pressure vessels not only provide a source of mechanical support for the pressure applied to reactant materials and SCF, but also serve as a container for the supercritical fluid and material being processed. The processing limitations for such pressure vessels are typically limited to a maximum temperature in the range between about 400 degrees Celsius and 550 degrees Celsius and a maximum pressure in the range between about 0.2 GigaPascals (also referred hereinafter as “GPa”) and 0.5 GPa.

Processing material with supercritical fluids requires a container or capsule that is both chemically inert and impermeable to the solvent and any gases that might be generated by the process. In one approach, the material to be processed, along with a liquid that forms a supercritical fluid at elevated temperatures, is introduced into a capsule. The capsule is then sealed in air, placed in a high pressure apparatus, and heated. Upon heating and self-pressurization, the liquid provides a supercritical fluid. Contamination of the supercritical fluid may result from air introduced during filling of the capsule, from moisture adsorbed in the interior of the capsule and/or on or in at least one of the materials being processed.

D'Evelyn et al., in U.S. Pat. No. 7,125,453, (herein “D'Evelyn et al.”) suggests a capsule that is evacuated of air prior to filling the capsule with the solvent that will become a supercritical fluid, e.g., ammonia, followed by sealing of the capsule. The capsule generally comprises a body that is filled with solid materials, followed by welding on a lid with a pre-configured fill tube. The capsule is evacuated through the fill tube and then the capsule is filled with a condensable solvent such as ammonia by flowing solvent vapor into the capsule, which is chilled to a temperature at which the solvent vapor will condense. In the case of ammonia, this corresponds approximately to dry ice temperature (−77° C.) or below. Although effective, D'Evelyn has limitations, that is, the capsule device may become deformed and/or rupture during handling or under supercritical processing conditions.

From the above, it is seen that improved techniques for processing supercritical fluids are highly desired.

### BRIEF SUMMARY OF THE INVENTION

According to the present invention, techniques related to a device and method for processing supercritical fluids are provided. In particular, the invention provides a capsule device and related method to be used with high pressure apparatus. More particularly, the invention relates to a capsule used in conjunction with a high-pressure apparatus for processing at least one material in a supercritical fluid. Merely by way of example, the invention can be applied to growing crystals of GaN, AlN, InN, InGaN, AlGaN, AlInGaN, and others for manufacture of bulk or patterned substrates. Such bulk or patterned substrates can be used for a variety of applications including optoelectronic devices, lasers, light emitting diodes, solar cells, photodetectors, and integrated circuits, transistor devices, other device structures, photoelectrochemical water splitting and hydrogen generation, and others.

In a specific embodiment, the present invention provides an improved capsule for processing materials or growing crystals in supercritical fluids. The capsule is scalable up to very large volumes and is cost effective according to a preferred embodiment. In conjunction with suitable high pressure apparatus, the capsule is capable of processing materials at pressures and temperatures of 0.2-2 GPa and 400-1200° C., respectively. Of course, there can be other variations, modifications, and alternatives.

In an alternative specific embodiment, the capsule has a least one wall, a closed end, and a sealed end. The sealed end is configured with at least one fill tube and both the closed end and the sealed end are fitted with reinforcement disks, respectively. Each of the disks is bonded to the capsule end and fabricated from a material with a higher modulus and yield strength than the modulus and yield strength of the particular material from which the capsule is fabricated.

In yet an alternative embodiment, the present invention provides a method for processing materials in supercritical fluids within a capsule at high pressure and high temperature. The method includes loading at least one material into the interior volume of the capsule and welding a lid with a fill tube onto the open end of the capsule. The method includes purging the interior of the capsule of air, moisture, and other contaminants by way of a gas flow directed from at least one end of the capsule interior to the other. The method includes filling the capsule with liquid solvent with the capsule maintained at a temperature between one and 50 degrees Celsius below the temperature of the solvent delivery system and sealing the fill tube without exposing the interior to atmosphere.

Still further, the present invention provides a capsule for processing materials in supercritical fluids at high pressure and high temperature. The capsule includes a cylindrical member capable of being insertable, which has a first end and a second end and a length. The cylindrical member is characterized by a material thickness and a first Young's modulus and a first yield strength. In a specific embodiment, the material thickness is capable of deformation upon a change of a first state to a second state of a material within an interior region of the cylindrical member. In a specific embodiment, the first state can be a low temperature (e.g., 25 degrees Celsius) and low pressure state (e.g., 10 atm) while the second state can be a high temperature (e.g., 700 degrees Celsius) and high pressure state, (e.g., 0.8 GPa) for a silver capsule processing GaN and NH₄F in ammonia for GaN crystal growth. In a specific embodiment, the capsule can also include a closed end provided at the first end and a sealed end provided at the second end. The capsule has at least one fill tube disposed on a portion of the sealed end. In a specific embodiment, the fill tube has an opening operably coupled to the interior region of the cylindrical member. The capsule also has a first reinforcement member mechanically coupled to the closed end and a second reinforcement member mechanically coupled to the sealed end. In a specific embodiment, the first reinforcement member and the second reinforcement member are configured to maintain a cylindrical shape of the cylindrical member free from any substantial deformation.

Moreover, the present invention provides a method for processing materials in supercritical fluids within a capsule at high pressure and high temperature. In a specific embodiment, the method includes loading at least one material into an interior volume of the capsule, which has a closed end and an open end. In a specific embodiment, the method also includes attaching a lid with a fill tube onto the open end of the capsule to seal the lid to capsule. The method includes purging the interior of the capsule of air, moisture, and other contaminants according to a specific embodiment. Optionally, purging may include injecting gas flow (e.g., argon and/or nitrogen) directed from a closed end or directed from the sealed end.

Depending upon the embodiment, the present method can also includes one of a plurality of optional steps. Optionally, the method includes forming a crystalline material from a process of the superheated solvent. Additionally, the method includes removing thermal energy from the capsule to cause a temperature of the capsule to change from a first temperature to a second temperature, which is lower than the first temperature. The method also includes removing a first flange and a second flange from the high pressure apparatus and moving a mechanical member, using a hydraulic drive force, from the first region of the cylindrical capsule region toward the second region to transfer the capsule out of the cylindrical capsule region.

Benefits are achieved over pre-existing techniques using the present invention. In particular, the present invention uses a high pressure treatment apparatus for growth of crystals such as GaN, AlN, InN, InGaN, and AlInGaN, and others. In a specific embodiment, the present method and apparatus can also use reinforcement members to add structural strength to a capsule, which is configured to be inserted in the treatment apparatus. Depending upon the embodiment, the present apparatus and method can be manufactured using conventional materials and/or methods according to one of ordinary skill in the art. In conjunction with a suitable high pressure apparatus, the present apparatus and method enable cost-effective crystal growth and materials processing under extreme pressure and temperature conditions in batch volumes larger than 0.3 liters, larger than 1 liter, larger than 3 liters, larger than 10 liters, larger than 30 liters, larger than 100 liters, and larger than 300 liters. The present apparatus and method improve the reliability and robustness of capsule filling, handling, and processing at high pressure and high temperature, increasing yields and decreasing overall process costs. Depending upon the embodiment, one or more of these benefits may be achieved. These and other benefits may be described throughout the present specification and more particularly below.

The present invention achieves these benefits and others in the context of known process technology. However, a further understanding of the nature and advantages of the present invention may be realized by reference to the latter portions of the specification and attached drawings.

### BRIEF DESCRIPTION OF THE DRAWINGS

FIG. 1 is a simplified diagram of a capsule device for supercritical fluids according to an embodiment of the present invention.

FIG. 2 is a simplified diagram of a capsule device for supercritical fluids according to another embodiment of the present invention.

FIG. 3 is a simplified diagram of a capsule device including an interior region for supercritical fluids according to an embodiment of the present invention.

FIG. 4 is a simplified diagram of a method for using a capsule device according to an embodiment of the present invention.

### DETAILED DESCRIPTION OF THE INVENTION

According to the present invention, techniques related to a device and method for processing supercritical fluids are provided. In particular, the invention provides a capsule device and related method to be used with high pressure apparatus. More particularly, the invention relates to a capsule used in conjunction with a high-pressure apparatus for processing at least one material in a supercritical fluid. Merely by way of example, the invention can be applied to growing crystals of GaN, AlN, InN, InGaN, AlGaN, AlInGaN, and others for manufacture of bulk or patterned substrates. Such bulk or patterned substrates can be used for a variety of applications including optoelectronic devices, lasers, light emitting diodes, solar cells, photodetectors, and integrated circuits, transistor devices, other device structures, photoelectrochemical water splitting and hydrogen generation, and others.

Before describing specific embodiments of the present invention, I discovered certain limitations with D'Evelyn, as the capsule becomes progressively larger. Evacuation of the capsule is a relatively convenient means for removing air and moisture, which could otherwise contaminate the subsequent process. However, the 14.7 pounds-per-square-inch pressure differential across the ends and wall of the capsule while evacuated could cause deformation and/or buckling, particularly for capsules larger than several inches in dimension and even more particularly when the capsule is fabricated from a soft metal such as annealed silver or gold. Additionally, flowing solvent vapor into a chilled capsule is convenient with small capsules but becomes progressively less practical as the capsule dimensions become larger than several inches. These and other limitations have been overcome by way of one or more embodiments of the present invention. Details of the embodiments of the present invention can be found throughout the present specification and more particularly below.

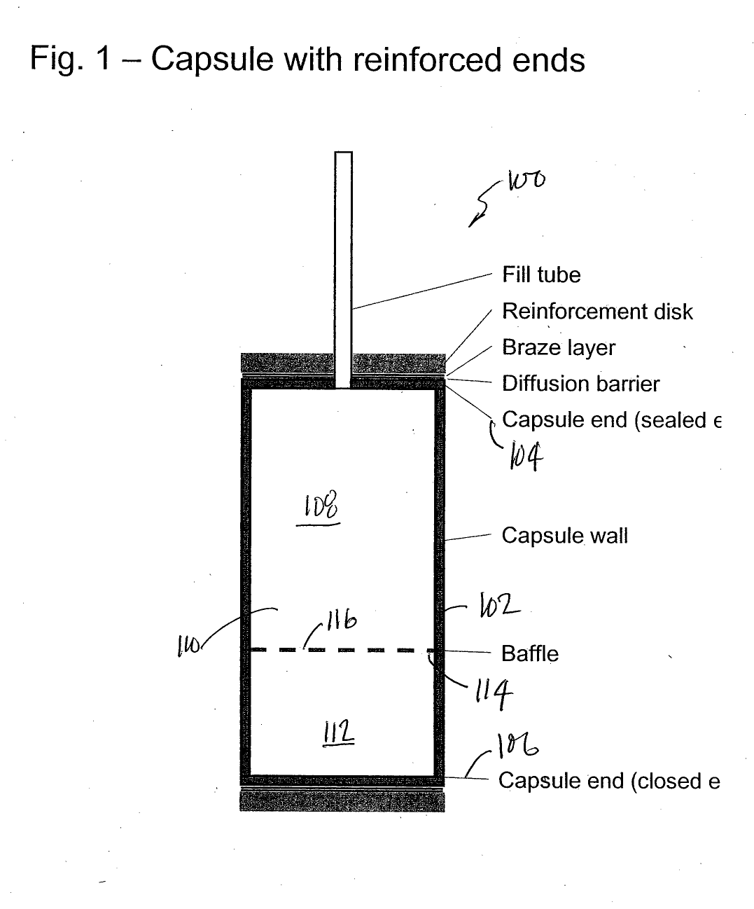

An assembled inventive capsule is shown in FIG. 1, which is a simplified diagram and should not unduly limit the scope of the claims herein. The capsule comprises at least one wall, a closed end, shown on the bottom in FIG. 1, and a sealed end, shown on top. The closed end may be attached to the capsule wall prior to use by means of a butt weld. The length-to-diameter ratio of the capsule, including the wall, the closed end, and the sealed end, not including the fill tube, should be at least 2:1 and more preferably lies in the range between 5:1 and 15:1. The length of the fill tube may be between 0.2 inch and 20 inches. Of course, there can be other variations, modifications, and alternatives.

Referring to the drawings in general and to FIG. 1, in particular, it will be understood that the illustrations are for the purpose of describing a preferred embodiment of the invention and are not intended to limit the invention thereto. Turning again to FIG. 1, capsule 100 has a closed end 106, at least one wall 102 adjoining the closed end 106 and extending therefrom, and a sealed end 104 adjoining the at least one wall 102 opposite the closed end 106. Closed end 106, the at least one wall 102, and sealed end 104 define a closed chamber 110 within the capsule 100 for containing at least one material 108 and a solvent 112 that becomes a supercritical fluid at a high pressure and high temperature (also referred to herein as “HPHT”). HPHT conditions encompass temperatures greater than about 100 degrees Celsius and pressures greater than about 1 atmosphere. In some applications the fluid may remain subcritical at HPHT, that is, the pressure or temperature may be less than the critical point. However, in all cases of interest here, the fluid is superheated, that is, the temperature is higher than the boiling point of the fluid at atmospheric pressure. The term “supercritical” will be used throughout to mean “superheated,” regardless of whether the pressure and temperature are greater than the critical point, which may not be known for a particular fluid composition with to dissolved solutes. Of course, there can be other variations, modifications, and alternatives.

Capsule 100 is chemically inert and impermeable with respect to the at least one material 110, solvent 112, and the supercritical fluid formed by the solvent 112. Capsule 100 is preferably impermeable to at least one of hydrogen, oxygen, and nitrogen. Closed end 106, at least one wall 102, and sealed end 104 each have a thickness of between about 0.2 mm and about 10 mm according to a specific embodiment. Other thicknesses can also be used depending upon the specific embodiment.

Capsule 100 is formed from a deformable material to allow expansion of the capsule as pressure increases within the capsule 100, thus, preventing the capsule 100 from bursting, as long as a suitable restraint is present to prevent excess capsule deformation. In a specific embodiment, the deformable material may be made of a suitable material such as copper, copper-based alloy, gold, silver, palladium, platinum, iridium, ruthenium, rhodium, osmium, titanium, vanadium, chromium, iron, iron-based alloy, nickel, nickel-based alloy, zirconium, niobium, molybdenum, tantalum, tungsten, rhenium, combinations thereof, and the like. In another embodiment, capsule 100 is formed from a cold-weldable material, such as, but not limited to, at least one of copper, copper-based alloy, gold, silver, palladium, platinum, iridium, ruthenium, rhodium, osmium, iron, iron-based alloy, nickel, nickel-based alloy, molybdenum, and combinations thereof. Iron-base alloys that may be used to form capsule 100 include, but are not limited to, stainless steels. Nickel-base alloys that may be used to form capsule 100 include, but are not limited to, inconel, hastelloy, and the like. Again, there can be other variations, modifications, and alternatives.

Capsule 100 may also be provided with at least one baffle 114, which divides chamber 108 into two separate regions. The two regions are in fluid communication with each other, as baffle 114 has a plurality of through-holes 116, or openings. Thus, a fraction of the cross-sectional area of the baffle 114 is open. In a specific embodiment, baffle 114 has a fractional open area of between about 0.5% and about 30%, but can also have other percentages. Baffle 114 is formed from at least one of copper, copper-based alloy, gold, silver, palladium, platinum, iridium, ruthenium, rhodium, osmium, titanium, vanadium, chromium, iron, iron-based alloy, nickel, nickel-based alloy, zirconium, niobium, molybdenum, tantalum, tungsten, rhenium, silica, alumina, and combinations thereof. Iron-base alloys that may be used to form baffle 114 include, but are not limited to, stainless steels. Nickel-base alloys that may be used to form baffle 114 include, but are not limited to, inconel, hastelloy, and the like. Baffle 114 serves the purpose of confining the at least one (or more) material 110 to a specific region or end of chamber 108 while permitting solvent 112 and, under HPHT conditions, supercritical fluid, to migrate throughout chamber 108 by passing freely through through-holes 116 in baffle 114. Often times, this feature is particularly useful in applications such as crystal growth, in which the supercritical fluid transports the at least one material 110, a nutrient material, from one region of the chamber 108, defined by placement of baffle 114, to another region where crystal growth on seed crystals take place. A larger volume may be provided for the growth region relative to the nutrient region, for example, by 50-300%. In the illustrated embodiment, appropriate for crystal growth when the solubility of the material to be recrystallized is an increasing function of temperature, the growth zone is located above the nutrient zone. In other embodiments, appropriate for crystal growth when the solubility of the material to be recrystallized is a decreasing function of temperature, i.e., retrograde solubility, the growth zone is located below the nutrient zone.

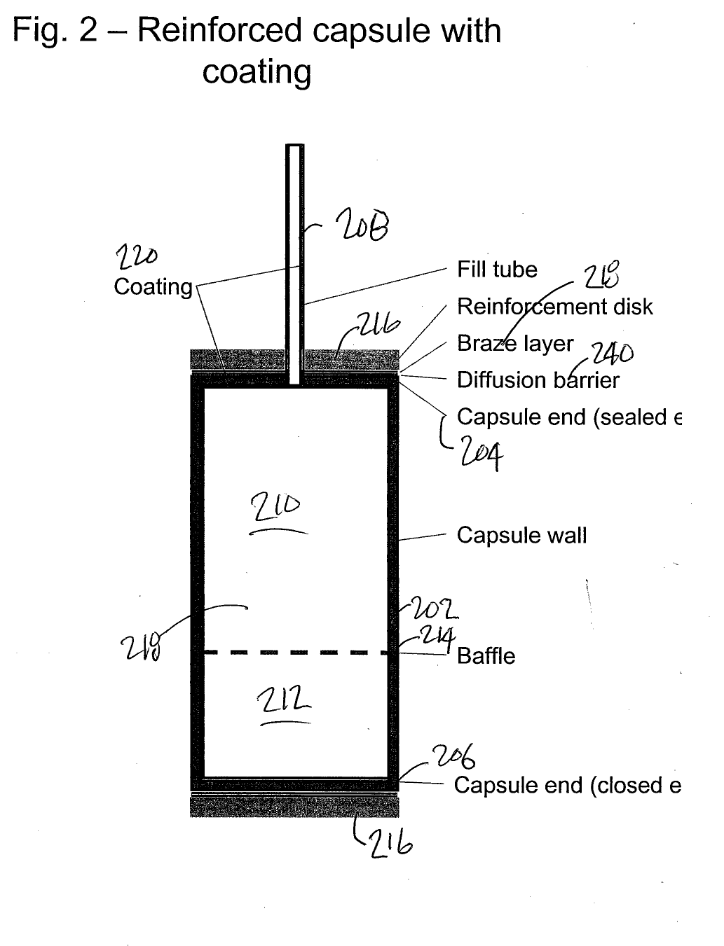

In a specific embodiment, shown in FIG. 2, at least one coating 220 is disposed on an inner surface of at least one of closed end 206, the at least one wall 202, and sealed end 204 of capsule 200, including fill tube 208. When capsule 200 includes baffle 214, the at least one coating 220 is disposed on baffle 214 as well. Coating 220 may serve the purpose of enhancing the impermeability and resistance of capsule 200 to chemical attack by its contents. Coating 220 has a thickness of between about 0.5 micron and about 250 microns. Coating 220 is formed from a material that is different from that used to form closed end 206, the at least one wall 202, and sealed end 204 and comprises at least one of: nickel; rhodium; gold; silver; palladium; platinum; ruthenium; iridium; tantalum; tungsten; rhenium; MCₓN_{y} O_{z}, wherein M is at least one of aluminum, boron, silicon, titanium, vanadium, chromium, yttrium, zirconium, lanthanum, a rare earth metal, hafnium, tantalum, tungsten, and wherein each of x, y, and z is between 0 and 3 (i.e., 0<x, y, z<3); and combinations thereof.

Capsule 200 may further include a diffusion barrier coating (not shown) disposed between coating 220 and the inner surface of at least one of closed end 206, the at least one wall 202, and sealed end 204 to reduce interdiffusion between closed end 206, the at least one wall 202, sealed end 204, and coating 220. The diffusion barrier is formed from a material that is different from that of coating 220, closed end 206, the at least one wall 202, and sealed end 204 and comprises at least one of nickel, rhodium, platinum, palladium, iridium, ruthenium, rhenium, tungsten, molybdenum, niobium, silver, iridium, tantalum, MCₓN_{y}O_{z}, wherein M is at least one of aluminum, boron silicon, titanium, vanadium, chromium, yttrium, zirconium, lanthanum, a rare earth metal, hafnium, tantalum, tungsten, and wherein each of x, y, and z is between 0 and 3 (i.e., 0<x, y, z<3); and combinations thereof. The diffusion barrier has a thickness of between about 10 nm and about 100 microns according to a specific embodiment, but can be others.

Referring back to FIG. 2, the closed end and the sealed end of the capsule each comprise a reinforcement disk or member 216, bonded to the capsule end and fabricated from a material with a higher modulus and yield strength than that of the material from which the capsule is fabricated. Depending upon the embodiment, the term “bonded” is not intended to be limiting and should be interpreted by ordinary meaning used by one of ordinary skill in the art. The inner portion of the ends may comprise the same material as the capsule wall. The outer portion of the ends comprises a material, the reinforcement disk, with a higher modulus and yield strength that that of the inner portion. The reinforcement disk may be fabricated from steel, stainless steel, palladium, platinum, iridium, ruthenium, rhodium, osmium, titanium, vanadium, chromium, iron, iron-based alloy, nickel, nickel-based alloy, zirconium, niobium, molybdenum, tantalum, tungsten, rhenium, combinations thereof, and the like. The thickness of the reinforcement disk may be between 0.050 inches and 2 inches. The diameter of the reinforcement disk may be equal, to within about 0.050 inches, of the diameter of the remainder of the respective capsule end. Of course, there can be other variations, modifications, and alternatives.

In a specific embodiment, the closed end and the sealed end of the capsule may further comprise a braze alloy 218, to effect a bond between the inner portion of the capsule end and the reinforcement disk. The braze alloy may comprise at least one of copper, silver, gold, nickel, or palladium. The braze may be applied as a foil with a thickness between 0.001 inch and 0.025 inch and the bond may be effected by heating the capsule end/braze/reinforcement stack above the liquidus temperature of the braze alloy under a suitable atmosphere, such as argon, argon/hydrogen, or hydrogen. The closed end and the sealed end of the capsule may further comprise a diffusion barrier 240 to inhibit diffusion of one or more elemental constituents of the reinforcement disk into and through the inner portion of the capsule end, thereby contaminating the process. The diffusion barrier 240 may comprise a suitable material such as nickel, rhodium, platinum, palladium, iridium, ruthenium, rhenium, tungsten, molybdenum, niobium, silver, iridium, tantalum, MCₓN_{y}O_{z}, wherein M is at least one of aluminum, boron silicon, titanium, vanadium, chromium, yttrium, zirconium, lanthanum, a rare earth metal, hafnium, tantalum, tungsten, and wherein each of x, y, and z is between 0 and 3 (i.e., 0<x, y, z<3); and combinations thereof. The diffusion barrier 240 has a thickness of between about 10 nm and about 100 microns.

The sealed end may further comprise a fill tube 208, fabricated from the same material as the inner portions of the capsule ends and of the capsule wall according to a specific embodiment. The fill tube may have an outer diameter between about 0.1 inch and about 1 inch and a wall thickness between about 0.010 inch and about 0.250 inch. The fill tube may be attached to the capsule end by arc welding, electron-beam welding, brazing, or the like, either before, during, or after bonding the reinforcement disk to the inner portion of the capsule end. The closed end may also further comprise a fill tube.

Sealed end 204 is formed after introducing the at least one material 210 and solvent 212 into chamber 218. In one embodiment, prior to forming the sealed end, the at least one wall 202 and closed end 206 define an open chamber 218 into which the at least one material 210 and—optionally—baffle 214 are placed. The at least one material 210 to be processed in a supercritical fluid at high pressure and high temperature is added to the capsule inside a glove box or another controlled-atmosphere container. The sealed end, with the fill tube still open, may then be attached to the open end of the capsule. The attachment of the sealed end to the open end of the capsule may be performed by arc welding, electron-beam welding, brazing, or the like. The attachment may be performed in a glove box or other controlled-atmosphere container. The portion of the capsule wall proximate to the closed end may be chilled or cooled during the attachment of the sealed end so as to avoid overheating, sublimation, evaporation, or decomposition of the at least one material.

The capsule is then coupled to a gas source by means of at least one fill tube, preferably without exposing the contents of the capsule to air according to a specific embodiment. The gas source may comprise at least one of nitrogen, argon, hydrogen, helium, and solvent vapor, among others. In an embodiment, both a fill tube located on the closed end of the capsule and a fill tube located on the sealed end of the capsule are coupled to a gas source and/or exhaust. In this embodiment, purge gas introduced through one fill tube will pass through the length of the capsule before exhausting through the other fill tube, providing for efficient removal of gas phase contaminants.

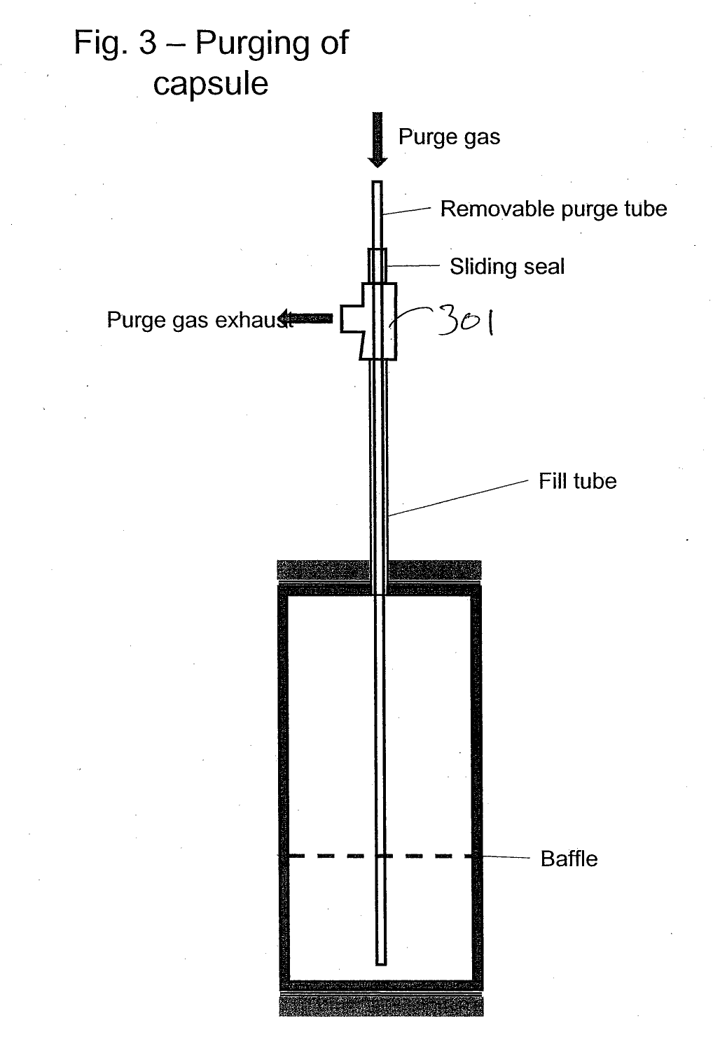

In another embodiment, shown in FIG. 3, a purge tube 301 is placed inside the fill tube and positioned so that one end is proximate to the closed end of the capsule. The purge tube may be fabricated from at least one of copper, copper-based alloy, gold, silver, palladium, platinum, iridium, ruthenium, rhodium, osmium, iron, iron-based alloy, nickel, nickel-based alloy, molybdenum, and combinations thereof Iron-base alloys that may be used to form the purge tube include, but are not limited to, stainless steels. Nickel-base alloys that may be used to form the purge tube include, but are not limited to, inconel, hastelloy, and the like. The outer diameter of the purge tube may be less than the inner diameter of the fill tube by at least 0.010 inch, as shown. The purge tube may be coupled to the fill tube by means of a tee fitting 303 or other suitable technique, so that purge gas introduced through the purge tube will exit near the closed end of the capsule, pass through the length of the capsule before exhausting though the annular space in the fill tube outside the purge tube and the tee fitting, providing for efficient removal of gas phase contaminants according to a specific embodiment. The interface between the tee fitting 303 and the purge tube 301 may be a sliding seal, for example, an O-ring or a differentially-pumped set of Teflon seals or O-rings. The rate of flow of the purge gas may be in the range between 0.05 and 10 standard liters per minute. The capsule may be heated, for example, to a temperature between 25 degrees Celsius and 500 degrees Celsius during the purge operation, in order to more efficiently remove water and other adsorbed contaminants. After shutting off flow of the purge gas, solvent vapor, for example, gas phase ammonia, may be flowed through the capsule in order to remove most or all of the purge gas.

In a specific embodiment, the inlet of the gas flow, for example, the second fill tube or the purge tube (cf. FIG. 3) is then coupled to a source of liquid solvent. The capsule and fill tubes may be cooled, or the liquid solvent delivery system and transfer lines heated, so that the former are cooler by between one and 50 degrees Celsius than the latter. Liquid solvent is then introduced into the capsule at a rate between 0.1 and 1000 grams per minute. In one embodiment, the purge exhaust is closed and the solvent vapor above the liquid is forced to condense into liquid during the filling operation. In this embodiment, the capsule may be actively cooled in order to dissipate the heat released by condensation of the solvent vapor. In another embodiment, the purge exhaust is fitted with a check valve so that residual purge gas or solvent vapor is allowed to exit when the pressure exceeds a predetermined threshold, but air or other gases are not allowed to flow backward into the capsule. The quantity of solvent in the capsule may be determined by using a liquid delivery system with the capability for accurately monitoring and controlling the mass of liquid delivered. If solvent gas is allowed to exhaust during liquid filling, in the case where ammonia is the solvent, the quantity of vented solvent may be determined by trapping it in aqueous solution and measuring the change in pH and this quantity subtracted from the total liquid delivered to determine the quantity of liquid in the capsule. An analogous method for determining the quantity of vented solvent may be performed in cases where the solvent is different from ammonia.

Following filling of the capsule, the purge tube, if present, may be removed. The fill tube(s) are sealed, in order to complete the formation of the sealed end of the capsule. Once sealed, the closed chamber 110 within capsule 100 is substantially air-free, and the at least one material 108 contained therein can be processed with reduced risk of contamination. Of course, there can be other variations, modifications, and alternatives.

In a specific embodiment sealed end 104 is formed by pinching off or collapsing a portion of the at least fill tube to form a weld. If the at least one fill tube is formed from a cold-weldable material, then pressure may be mechanically applied to points on an outer surface of the at least one fill tube to pinch a portion of the inner surface of the at least one fill tube together to form a cold-welded bond, thereby forming sealed end 104. Alternatively, sealed end 104 can be formed by heating a portion of the outer surface of the at least one fill tube to collapse the portion of the at least one fill tube and form a hot weld at the inner surface of the at least one fill tube at that point. The hot weld may be formed by torch welding, arc welding, ultrasonic welding, vibratory welding, magnetic pulse welding, or the like. In another embodiment, at least one fill tube is sealed by means of brazing. Sealing of the fill tube should be performed without any air exposure of the interior of the capsule.

In a specific embodiment, the cylindrical member is characterized by a material thickness and a first Young's modulus and a first yield strength. In a specific embodiment, the material thickness is capable of deformation upon a change of a first state to a second state of a material within an interior region of the cylindrical member. That is, the material thickness is sufficiently thin to lead to deformation and rupture according to a specific embodiment. As shown, the closed end is closed end provided at the first end and the sealed end provided at the second end. As described before, any of the features of the other embodiments can be used herein.

As shown in FIG. 2, the capsule has at least one fill tube 208 disposed on a portion of the sealed end. In a specific embodiment, the fill tube has an opening operably coupled to the interior region of the cylindrical member. As also shown in a preferred embodiment, the capsule has a first reinforcement structure integrally coupled to the closed end and a second reinforcement structure integrally coupled to the sealed end. In a specific embodiment, the first reinforcement structure and the second reinforcement structure are configured to maintain a cylindrical shape of the cylindrical member free from any substantial deformation. That is, the reinforcement members are configured to provide mechanical support to the capsule during high temperature and pressure processing according to a specific embodiment. Of course, there are other variations, modifications, and alternatives.

A method for processing materials in supercritical fluids within a capsule at high pressure and high temperature according to a specific embodiment is provided below.

1. Load at least one material into an interior volume of the capsule, which has a closed end and an open end;

2. Attach a lid with a fill tube onto the open end of the capsule to seal the lid to capsule;

3. Purge the interior of the capsule of air, moisture, and other contaminants by way of injecting gas flow directed from a closed end or directed from the sealed end followed by injecting solvent vapor into the capsule;

4. Fill the interior volume of the capsule with condensable solvent in a liquid form;

5. Determine volume of solvent in capsule;

6. Seal fill tube;

7. Place capsule in high pressure apparatus;

8. Heat capsule to general supercritical fluid and crystalline material;

9. Remove energy from capsule;

10. Remove capsule;

11. Remove material from capsule, which has been opened; and

12. Perform other steps, as desired.

The above sequence of steps provides a method according to an embodiment of the present invention. In a specific embodiment, the present invention provides a method and capsule device suitable for large scale processing of crystalline materials using supercritical fluids and the like. Other alternatives can also be provided where steps are added, one or more steps are removed, or one or more steps are provided in a different sequence without departing from the scope of the claims herein. Details of the present method and structure can be found throughout the present specification and more particularly below.

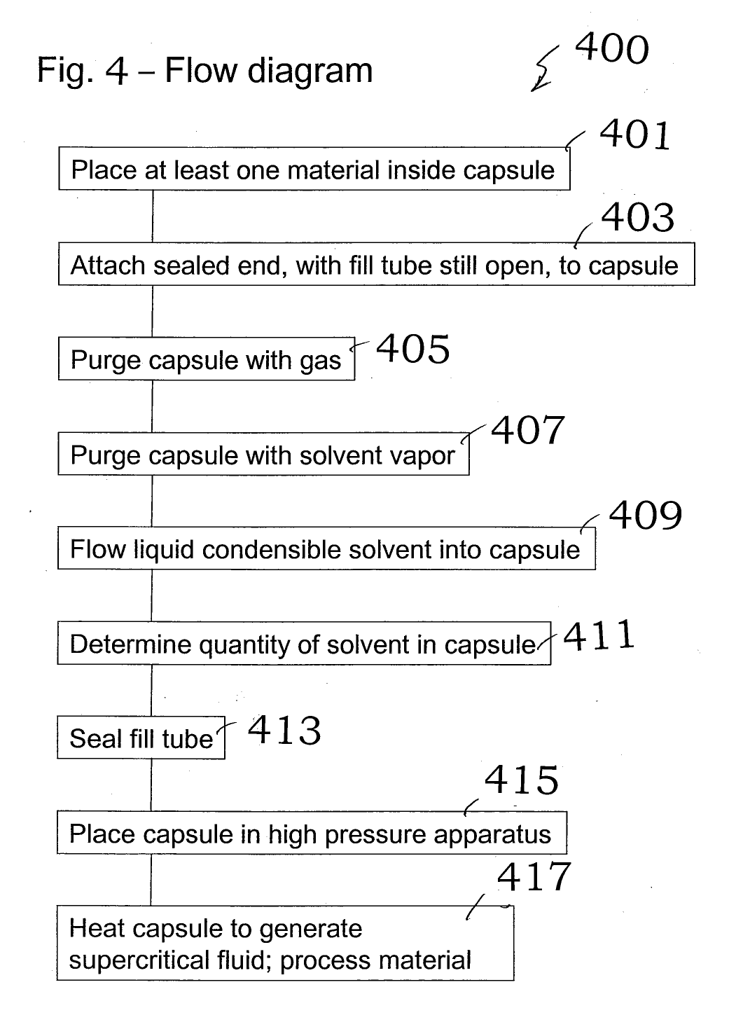

FIG. 4 is a simplified diagram 400 of a method for using a capsule device according to an embodiment of the present invention. This diagram is merely an example, which should not unduly limit the scope of the claims herein. One of ordinary skill in the art would recognize other variations, modifications, and alternatives. As shown, the present method is for processing materials in supercritical fluids within a capsule at high pressure and high temperature. In a specific embodiment, the present method includes loading at least one material (step 401) into an interior volume of the capsule, which has a closed end and an open end, as previously described.

In a specific embodiment, the method includes attaching (step 403) a lid with a fill tube onto the open end of the capsule to seal the lid to capsule. In a specific embodiment, the fill tube remains open or can be opened later.

The method includes purging the interior of the capsule of air, moisture, and other contaminants according to a specific embodiment. As shown, the method includes purging comprising injecting gas flow directed from a closed end or directed from the sealed end. The gas flow removes any particulate contaminates from an interior region of the capsule. In a specific embodiment, the method uses an inert gas such as argon and/or nitrogen gas to purge the capsule, but can be other gases as well. In a specific embodiment, the method purges the capsule with a solvent vapor, step 407, as shown. The solvent vapor can be similar to a condensable solvent used for processing of at supercritical conditions. Of course, there can be other variations, modifications, and alternatives.

Referring again to FIG. 5, the method includes introducing (step 409) condensable solvent into the capsule to fill it. In a specific embodiment, the condensable solvent is maintained at a temperature between one and 50 degrees Celsius below a temperature of the solvent delivery system according to a specific embodiment. In a specific embodiment, the method determines whether the volume of solvent in the capsule is suitable or desirable, step 411. If so, the method stops filling the capsule with the solvent according to a specific embodiment.

In a specific embodiment, the method includes sealing (step 413) the fill tube without exposing the interior to atmosphere. In a specific embodiment, the sealing method includes welding, arc welding, pinch sealing, ultrasonic welding, magnetic pulse welding, and brazing, other combinations of these techniques, and the like. Of course, there can be other variations, modifications, and alternatives. The capsule is then placed in a high pressure apparatus (step 413). As an example, such high pressure apparatus is described in U.S. patent application Ser. No. ______ (Attorney Docket No. 027364-000300US), commonly assigned, and hereby incorporated by reference here. The capsule is processed (step 417) to generate heat and process the material to form crystalline material according to a specific embodiment. Of course, there can be other variations, modifications, and alternatives.

The various embodiments of the capsule of the present invention, as described herein, are self-pressurizing. That is, the high pressures required for processing with supercritical fluids, rather than being externally applied to the capsule, are generated within the capsule itself. The capsule is self-pressurizable up to between about 1 atm (.apprxeq. 1 bar) and about 8 GPa. In one embodiment, the capsule is pressurizable up to between about 0.5 GPa and about 8 GPa. In another embodiment, self-pressurizing capsule is pressurizable up to between about 0.5 GPa and about 2 GPa. As the capsule is heated, the vapor pressure of the solvent within capsule 12 increases. The vapor pressure of the solvent at a given temperature can be determined from the phase diagram of the solvent. At sufficiently high processing temperatures and pressures—such as, for example, above about 0.5 GPa and about 550 degrees Celsius and, preferably, at pressures between 0.5 GPa and 2 GPa and temperatures between 550 degrees Celsius and about 1200 degrees Celsius—the solvent becomes a supercritical fluid. As the internal pressure within the capsule increases, the walls of the capsule deform outward and press against a restraint. In one embodiment, the restraint is a zero-stroke pressure apparatus, as described in US patent application 2003/0140845A1, which is incorporated by reference herein. In another embodiment, the restraint is a cool-wall pressure apparatus, as described in US patent applications 2006/0177362A1 which is incorporated by reference in their entirety.

The capsule may be used to process a variety of materials, including, but not limited to, high quality gallium nitride single crystals. Such gallium nitride single crystal are formed by: providing at least one gallium nitride source material to the chamber of the capsule; welding on the sealed end; purging the chamber through the fill tube; filling the chamber with a predetermined quantity of a solvent that becomes a supercritical fluid at high temperature and high pressure; sealing the fill tube(s); disposing the sealed capsule within a high pressure apparatus; and subjecting the capsule to high pressure, high temperature conditions. For GaN, HPHT conditions include pressures and temperatures of 0.2-2 GPa and 400-1200° C., respectively.

While the above is a full description of the specific embodiments, various modifications, alternative constructions and equivalents may be used. In a specific embodiment, the present capsule can grow GaN crystals using a technique commonly known by one of ordinary skill in the art or other techniques. As an example, such technique include ammonothermal processes, hydrothermal processes, solvothermal processes, combination of these techniques, and others, and the like. Therefore, the above description and illustrations should not be taken as limiting the scope of the present invention which is defined by the appended claims.

What is claimed is:

1. A capsule for processing materials in supercritical fluids at high pressure and high temperature comprising:
a cylindrical member capable of being insertable, the cylindrical member comprising a first end and a second end and a length, the cylindrical member being characterized by a material thickness and a first Young's modulus and a first yield strength, the material thickness being capable of deformation upon a change of a first state to a second state of a material within an interior region of the cylindrical member;
a closed end provided at the first end;
a sealed end provided at the second end;
at least one fill tube disposed on a portion of the sealed end, the fill tube having an opening operably coupled to the interior region of the cylindrical member;
a first reinforcement member mechanically coupled to the closed end;
a second reinforcement member mechanically coupled to the sealed end; and
wherein the first reinforcement member and the second reinforcement member are configured to maintain a cylindrical shape of the cylindrical member free from any substantial deformation.

2. The capsule of claim 1 wherein the first reinforcement member is characterized by a second Young's modules, the second Young's modules is greater than the first Young's modulus.

3. The capsule of claim 2 wherein the first reinforcement member is characterized by a second yield strength, the second yield strength is greater than the first yield strength.

4. The capsule of claim 1 wherein the second reinforcement member is characterized by a second Young's modules, the second Young's modules is greater than the first Young's modulus.

5. The capsule of claim 2 wherein the second reinforcement member is characterized by a second yield strength, the second yield strength is greater than the first yield strength.

6. The capsule of claim 1 wherein the material thickness is made from a material selected from a group consisting of copper, copper-based alloy, gold, silver, palladium, platinum, iridium, ruthenium, rhodium, osmium, titanium, vanadium, chromium, iron, iron-based alloy, nickel, nickel-based alloy, zirconium, niobium, molybdenum, tantalum, tungsten, rhenium, combinations thereof.

7. The capsule of claim 6 wherein the material thickness is made from a material selected from a group consisting of silver, gold, and platinum.

8. The capsule of claim 1 wherein the inner region has a volume of about 1 liter or greater.

9. The capsule of claim 8 wherein the inner region has a volume of about 10 liters or greater.

10. The capsule of claim 1 wherein the first reinforcement member is made of a material selected from stainless steel, and nickel.

11. The capsule of claim 1 wherein the second reinforcement member is made of a material selected from stainless steel, and nickel.

12. The capsule of claim 1 wherein the interior region is subjected to a pressure of about 0.5 GPa and greater.

13. The capsule of claim 1 wherein the first reinforcement member is characterized as a disk shape.

14. The capsule of claim 1 wherein the second reinforcement member is characterized as a disk shape.

15. The capsule of claim 1 wherein the first reinforcement member mechanically coupled to the closed end is provided by a first braze joint; and wherein the second reinforcement member mechanically coupled to the sealed end is provided by a second braze joint.

16. The capsule of claim 1 wherein the closed end is continuous with the cylindrical member.

17. The capsule of claim 1 wherein the sealed end comprises a lid member welded to the second end.

18. The capsule of claim 1 further comprising a baffle disposed between a first region of the interior region and a second region of the interior region.

19. The capsule of claim 1 further comprising a first diffusion barrier layer provided between the first reinforcement member and the closed end and a second diffusion barrier layer provided between the second reinforcement member and the sealed end.

20. The capsule of claim 18 wherein the first diffusion barrier layer is selected from a group consisting of nickel, rhodium, platinum, palladium, iridium, ruthenium, rhenium, tungsten, molybdenum, niobium, silver, iridium, tantalum, MCₓN_{y}O_{z}, wherein M is at least one of aluminum, boron silicon, titanium, vanadium, chromium, yttrium, zirconium, lanthanum, a rare earth metal, hafnium, tantalum, tungsten, and wherein each of x, y, and z is between 0 and 3 (i.e., 0<x, y, z<3); and combinations thereof.

21. A method for processing materials in supercritical fluids within a capsule at high pressure and high temperature, the method comprising:
loading at least one material into an interior volume of the capsule, the capsule having a closed end and an open end;
attaching a lid with a fill tube onto the open end of the capsule to seal the lid to the capsule; and
purging the interior of the capsule of air, moisture, and other contaminants.

22. The method of claim 21 wherein the purging comprising injecting gas flow directed from a closed end or directed from the sealed end.

23. The method of claim 22 wherein the gas flow comprises argon and/or nitrogen gas.

24. The method of claim 22 wherein the gas flow comprises a vapor of a condensable solvent in a liquid form.

25. The method of claim 21, further comprising purging the interior of the capsule of the gas used for the initial purge step with solvent vapor.

26. The method of claim 21 further comprising filling the interior volume of the capsule with condensable solvent in a liquid form.

27. The method of claim 26 further comprising maintaining the condensable solvent at a temperature between one and 50 degrees Celsius below a temperature of the solvent delivery system.

28. The method of claim 21 further comprising sealing the fill tube without exposing the interior to atmosphere.

29. The method of claim 28 wherein the sealing comprises a method selected from welding, arc welding, pinch sealing, ultrasonic welding, magnetic pulse welding, and brazing.

30. The method of claim 26 wherein the condensable solvent is ammonia for formation of GaN crystals.

31. The method of claim 21 wherein the step of purging the interior of the capsule of air, moisture, and other contaminants is performed by means of a nested purge tube within the fill tube.

32. The method of claim 31 wherein the nested purge tube is removable.

33. The method of claim 28 further comprising the steps of placing the capsule in a high pressure apparatus; and heating the capsule to generate a supercritical fluid for growth of a GaN crystalline material.

34. The method of claim 33, wherein the step of heating the capsule to generate a supercritical fluid comprises heating to a temperature greater than 200 degrees Celsius.

35. The method of claim 34, wherein the step of heating the capsule to generate a supercritical fluid comprises heating to a temperature greater than 550 degrees Celsius and generating a pressure greater than 0.5 GPa.
